(19) United States
(12) Patent Application Publication
(10) Pub. No.: US 2024/0424637 A1
(43) Pub. Date: Dec. 26, 2024

(54) BACK GRINDING APPARATUS AND WEAR AMOUNT MEASURING METHOD USING THE SAME

(71) Applicant: SAMSUNG ELECTRONICS CO., LTD., Suwon-si (KR)

(72) Inventors: WONKEUN CHO, Suwon-si (KR); DONGHOON KWON, Suwon-si (KR)

(73) Assignee: SAMSUNG ELECTRONICS CO., LTD., Suwon-si (KR)

(21) Appl. No.: 18/412,053

(22) Filed: Jan. 12, 2024

(30) Foreign Application Priority Data
Jun. 26, 2023 (KR) 10-2023-0081915

(51) Int. Cl. B24B 49/12; B24B 49/18

(52) U.S. Cl. CPC B24B 49/12; B24B 49/186

(57) ABSTRACT

A back grinding apparatus includes a grinding wheel that is rotatable and movable in a vertical direction and including at least one abrasive, and a grinding gauge below the grinding wheel and configured to measure a wear amount of the at least one abrasive, where the grinding gauge includes a measuring body and a photoelectric sensor supported by the measuring body and configured to determine the wear amount of the at least one abrasive, and where the photoelectric sensor includes at least one light emitter, and at least one light receiver spaced apart from the at least one light emitter in a horizontal direction and configured to receive light emitted from the at least one light emitter.

### CROSS-REFERENCE TO RELATED APPLICATION

This application is based on and claims priority under 35 U.S.C § 119 to Korean Patent Application No. 10-2023-0081915, filed on Jun. 26, 2023 in the Korean Intellectual Property Office, the disclosure of which is incorporated by reference herein in its entirety.

### BACKGROUND

The present disclosure relates to a back grinding apparatus and a wear amount measuring method using the same, and more particularly, to a back grinding apparatus using a photoelectric sensor to measure a wear amount of grinding wheel abrasive and a wear amount measuring method using the same.

A semiconductor device may be fabricated through various processes. A semiconductor process may include a front-end-of-line (FEOL) process and a back-end-of-line (BEOL) process. A back grinding process may be performed after the FEOL process and before the BEOL process. The back grinding process may include thinning rear surfaces of substrates. The back grinding process may remove contaminants occurring in the FEOL process and may reduce a chip thickness.

To execute a back grinding process, the rear surface of the substrate may be grinded after performing a tape lamination process in which the substrate is attached with a tape. A grinding wheel may be used to grind the rear surface of the substrate. For example, an abrasive of the grinding wheel may grind the rear surface of the substrate.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a back grinding apparatus that may measure a wear amount of grinding wheel abrasive and a wear amount measuring method using the same.

One or more example embodiments provide a back grinding apparatus in which a wear amount of grinding wheel abrasive may be measured irrespective of substrate dispersion and a wear amount measuring method using the same.

One or more example embodiments provide a back grinding apparatus that may use a photoelectric sensor to measure a wear amount of grinding wheel abrasive and a wear amount measuring method using the same.

One or more example embodiments provide a back grinding apparatus that may cause a grinding gauge to move to an outside of a grinding wheel and a wear amount measuring method using the same.

Additional aspects will be set forth in part in the description which follows and, in part, will be apparent from the description, or may be learned by practice of the presented embodiments.

According to an aspect of an example embodiment, a back grinding apparatus may include a grinding wheel that is rotatable and movable in a vertical direction and including at least one abrasive, and a grinding gauge below the grinding wheel and configured to measure a wear amount of the at least one abrasive, where the grinding gauge includes a measuring body and a photoelectric sensor supported by the measuring body and configured to determine the wear amount of the at least one abrasive, and where the photoelectric sensor includes at least one light emitter, and at least one light receiver spaced apart from the at least one light emitter in a horizontal direction and configured to receive light emitted from the at least one light emitter.

According to an aspect of an example embodiment, a back grinding apparatus may include a spindle assembly that is rotatable and movable in a vertical direction and a grinding gauge below the spindle assembly, where the spindle assembly includes a driver configured to move the spindle assembly in the vertical direction, and a grinding wheel provided on a lower portion of the driver, where the grinding wheel includes a plurality of abrasives on a first surface of the grinding wheel and spaced apart in a circumferential direction of the grinding wheel, where the grinding gauge includes a measuring body and a photoelectric sensor provided on the measuring body and configured to determine a wear amount of at least one of the plurality of abrasives, where the photoelectric sensor includes at least one light emitter and at least one light receiver spaced apart from the at least one light emitter in a horizontal direction, and where the plurality of abrasives are between the at least one light emitter and the at least one light receiver.

According to an aspect of an example embodiment, a wear amount measuring method may include providing a grinding gauge below a grinding wheel, and measuring a wear amount of the grinding wheel, where the grinding wheel includes a wheel body, and a plurality of abrasives on a bottom surface of the wheel body and spaced apart along an edge of the wheel body, where the grinding gauge includes a measuring body, at least one light emitter, and at least one light receiver spaced apart from the at least one light emitter in a horizontal direction, where providing the grinding gauge below the grinding wheel includes positioning at least one of the plurality of abrasives between the at least one light emitter and the at least one light receiver, and where measuring the wear amount of the grinding wheel includes emitting light by the at least one light emitter toward at least one of the plurality of abrasives and measuring a wear amount of the at least one of the plurality of abrasives based on the light emitted by the at least one light emitter.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a spindle assembly and a chuck table according to one or more example embodiments;

FIG. 2 is a front view illustrating a spindle assembly and a chuck table according to one or more example embodiments;

FIG. 3 is a front view illustrating a back grinding apparatus according to one or more example embodiments;

FIG. 4 is a front view illustrating a back grinding apparatus according to one or more example embodiments;

FIG. 5 is a bottom view illustrating a grinding wheel and a grinding gauge according to one or more example embodiments;

FIG. 6 is a bottom view illustrating a grinding wheel and a grinding gauge according to one or more example embodiments;

FIG. 7 is a front view illustrating a grinding gauge according to one or more example embodiments;

FIG. 8 is a front view illustrating a grinding gauge according to one or more example embodiments;

FIG. 9 is a front view illustrating a grinding gauge according to one or more example embodiments;

FIG. 10 is a bottom view illustrating a grinding wheel and a grinding gauge according to one or more example embodiments;

FIG. 11 is a bottom view illustrating a grinding wheel and a grinding gauge according to one or more example embodiments;

FIG. 12 is a bottom view illustrating a grinding wheel and a grinding gauge according to one or more example embodiments;

FIG. 13 is a bottom view illustrating a grinding wheel and a grinding gauge according to one or more example embodiments;

FIG. 14 is a front view illustrating a spindle assembly and a grinding gauge according to one or more example embodiments; and

FIG. 15 is a flowchart illustrating a wear amount measuring method according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

D1 may indicate a first direction, D2 may indicate a second direction that intersects the first direction D1, and D3 may indicate a third direction that intersects each of the first direction D1 and the second direction D2. The first direction D1 may be referred to as an upward direction, and a direction opposite to the first direction D1 may be referred to as a downward direction. In addition, each of the second and third directions D2 and D3 may be referred to as a horizontal direction.

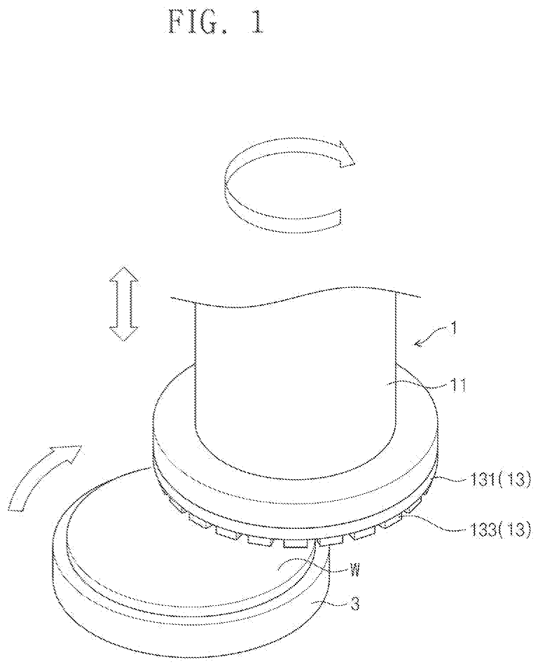

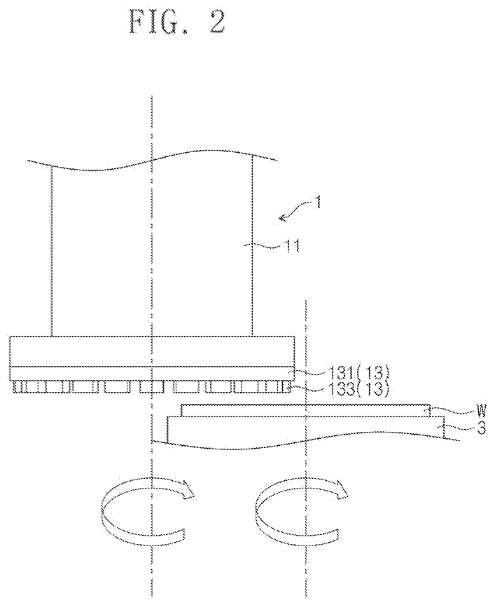

FIG. 1 is a perspective view illustrating a spindle assembly 1 and a chuck table 3 according to one or more example embodiments. FIG. 2 is a front view illustrating a spindle assembly 1 and a chuck table 3 according to one or more example embodiments.

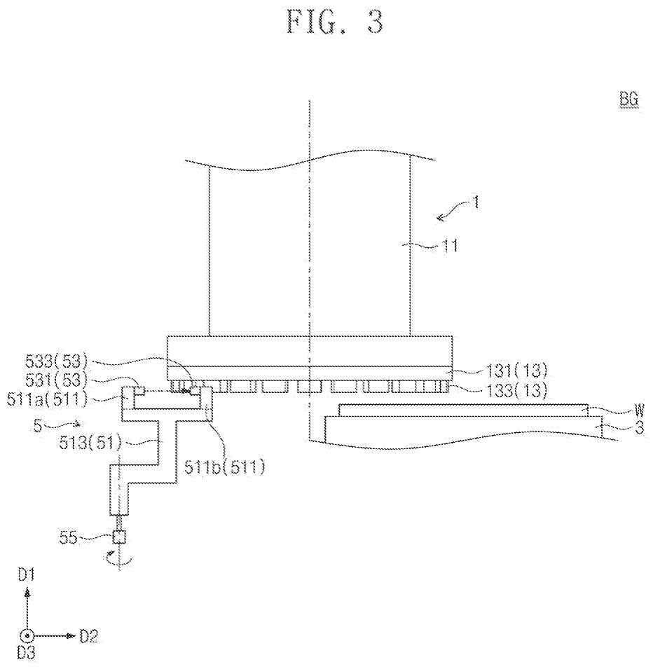

Referring to FIGS. 1 and 2, a back grinding apparatus (see BG of FIG. 3) may be provided. The back grinding apparatus BG may include a spindle assembly 1, a chuck table 3, and a grinding gauge (see 5 of FIG. 3).

The spindle assembly 1 may include a driver 11 and a grinding wheel 13. The driver 11 may be provided on an upper portion of the grinding wheel 13. For example, the driver 11 may be attached to the grinding wheel 13 through a bolt, an electromagnet, and/or a magnet, while being positioned on the upper portion of the grinding wheel 13. However, the assembly of the driver 11 and the grinding wheel 13 is not limited thereto, and may include any other suitable ways in which the driver 11 may drive the grinding wheel 13 to rotate and move. The driver 11 may control a rotation speed of the grinding wheel 13. The driver 11 may drive the grinding wheel 13 to move vertically such that a lower portion of the grinding wheel 13 may contact a substrate W. The term “substrate” may refer to a silicon (Si) wafer, but the disclosure is not limited thereto.

The grinding wheel 13 may be driven by the driver 11, and may be rotatable and vertically movable. The grinding wheel 13 may include a wheel body 131 and an abrasive 133. The wheel body 131 may have, for example, a plate shape. The wheel body 131 may have a circular shape. For example, the wheel body 131 may have a disk shape. The disclosure, however, is not limited thereto, and the wheel body 131 may have any other suitable shapes. The wheel body 131 may support the abrasive 133. The abrasive 133 may refer to a protrusion-like component as shown in FIG. 1, and may also refer to a grain-material coated on a surface of the grinding wheel 13 or other types of materials suitable for the use of the grinding wheel 13 as will be understood by one of ordinary skill in the art from the disclosure herein. For example, a plurality of abrasives 133 may be coupled to one surface of the wheel body 131. On the one surface of the wheel body 131, the plurality of abrasives 133 may be spaced apart from each other in a circumferential direction of the wheel body 131. A single abrasive 133 will be described below. The abrasive 133 may grind the substrate W, while being rotated by the driver 11. The abrasive 133 may include a material capable of grinding the substrate W. For example, the abrasive 133 may include diamond to grind the substrate W. The abrasive 133 may be provided in the form of broken segments. As the abrasive 133 is formed as segments, the abrasive 133 may be prevented from being distorted due to friction-induced thermal expansion during grinding.

The chuck table 3 may support the substrate W. The chuck table 3 may have a disk shape whose size is greater than that of the substrate W so as to place the substrate W on the chuck table 3. A vacuum line may be separately connected to an inner side of the chuck table 3, thereby vacuum adsorbing the substrate W. The chuck table 3 may be rotatable. The chuck table 3 may be equipped on its lower portion with a rotating unit that drives the chuck table 3 to rotate at a constant speed.

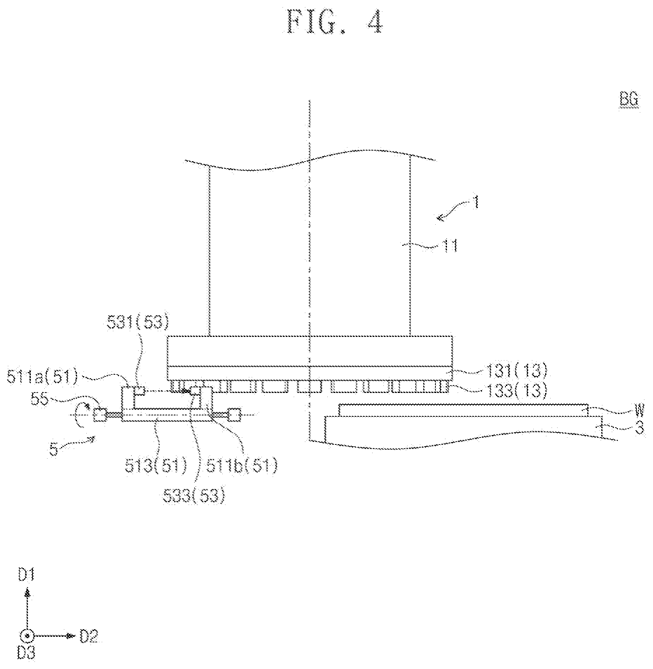

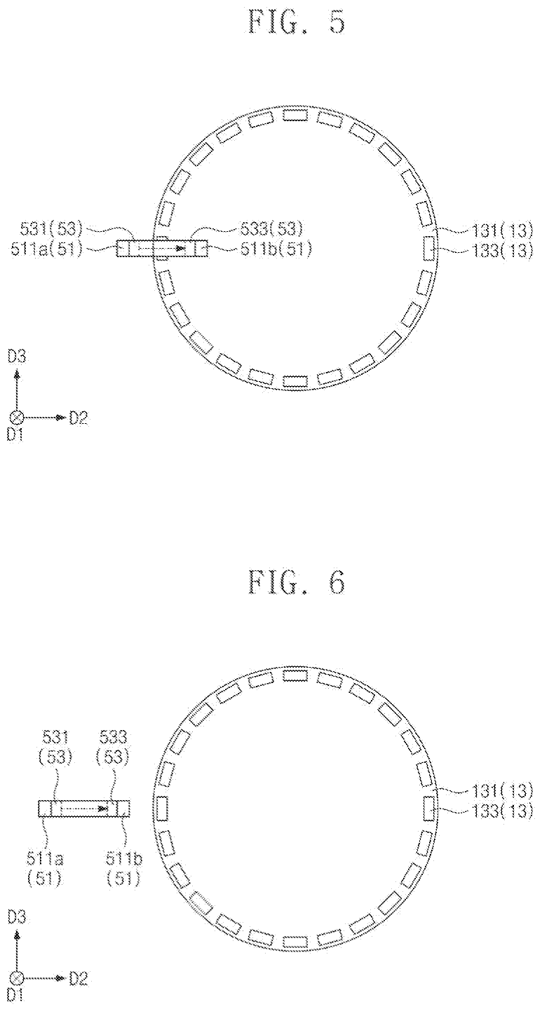

FIG. 3 is a front view illustrating a back grinding apparatus BG according to one or more example embodiments. FIG. 4 is a front view illustrating a back grinding apparatus BG according to one or more example embodiments. FIG. 5 is a bottom view illustrating a grinding wheel 13 and a grinding gauge 5 according to one or more example embodiments. FIG. 6 is a bottom view illustrating a grinding wheel 13 and a grinding gauge 5 according to one or more example embodiments.

Referring to FIGS. 3 to 6, a grinding gauge 5 may be provided. The grinding gauge 5 may be positioned below the spindle assembly 1. The grinding gauge 5 may be disposed below the grinding wheel 13. The grinding gauge 5 may measure a wear amount of the abrasive 133. In a plan view, the grinding gauge 5 may overlap the spindle assembly 1. The phrase “in a plan view” may indicate “when viewed from above.” The grinding gauge 5 may include a rotary motor 55, a measuring body 51, and a photoelectric sensor 53.

The measuring body 51 may support the photoelectric sensor 53. The measuring body 51 may include an upper measuring body 511 and a lower measuring body 513. The photoelectric sensor 53 may be provided on the measuring body 511. The lower measuring body 513 may support the upper measuring body 511. The upper measuring body 511 may include a first upper measuring body component 511a and a second upper measuring body component 511b. The first upper measuring body component 511a and the second upper measuring body component 511b may be protrusions or other structures extending from the measuring body 51 and configured to be provided with electronics or other components, such as a photoelectric sensor 53 including a light emitter 531 on one side (e.g., on the first upper measuring body component 511a) and a light receiver 533 on another side (e.g., on the second upper measuring body component 511b). The lower measuring body 513 may be provided. For example, the rotary motor 55 may be connected to the measuring body 51. The rotary motor 55 may drive the measuring body 51 to rotate and cause the grinding gauge 5 to move to an outside of the grinding wheel 13. The lower measuring body 513 may have any other suitable shapes. Referring to FIG. 3, the lower measuring body 513 may have an axis coincident with a rotation axis of the rotary motor 55. As the lower measuring body 513 is rotated by the rotary motor 55, the grinding gauge 5 may be positioned outside the grinding wheel 13. FIGS. 4 and 5 depict a relative positional relationship between the grinding wheel 13 and the measuring body 51 in a state before the rotation of the measuring body 51. For example, before the measuring body 51 is driven by the rotary motor 55, a portion of the measuring body 51 may be positioned at a region vertically below the grinding wheel 13. FIG. 6 depicts the grinding wheel 13 and the measuring body 51 after the measuring body 51 is rotated by the rotary motor 55. The rotary motor 55 may move the measuring body 51 outside the region vertically below the grinding wheel 13. Other shapes of the measuring body 51 will be discussed below.

The photoelectric sensor 53 may include a light emitter 531 and a light receiver 533. The light emitter 531 may emit light. The light emitter 531 and the light receiver 533 may be spaced apart from each other in a horizontal direction. The light receiver 533 may receive light emitted from the light emitter 531. A detection-target substance may cause the light emitted from the light emitter 531 to undergo a change such as reflection, transmission, and adsorption. The light receiver 533 may detect the change of light. The photoelectric sensor 53 may include a through-beam sensor, a diffuse-reflective sensor, and a retro-reflective sensor. A through-beam sensor will be mainly discussed below. Referring to FIGS. 3 to 5, the abrasive 133 may be positioned between the light emitter 531 and the light receiver 533. The abrasive 133 may block the light emitted from the light emitter 531, and thus the light receiver 533 may not receive the light. When the light receiver 533 receives the light emitted from the light emitter 531, the abrasive 133 may reduce intensity of light. When the abrasive 133 is worn to have a reduced height, the light receiver 533 may receive the light emitted from the light emitter 531. It is illustrated that one abrasive 133 is disposed between the light emitter 531 and the light receiver 533, but the disclosure is not limited thereto. For example, a plurality of abrasives 133 may be positioned between the light emitter 531 and the light receiver 533. The upper measuring body 511 may be provided with a light emitter 531 and a light receiver 533. For example, a first upper measuring body component 511a may include the light emitter 531. A second upper measuring body component 511b may include the light receiver 533. The light emitter 531 may be coupled to an inner lateral surface of the first upper measuring body component 511a. The light receiver 533 may be coupled to an inner lateral surface of the second upper measuring body component 511b. The inner lateral surface of the first upper measuring body component 511a may face the inner lateral surface of the second upper measuring body component 511b. Therefore, the light emitter 531 and the light receiver 533 may face each other. Before the measuring body 51 is rotated by the rotary motor 55, one of the light emitter 531 and the light receiver 533 may be positioned below the grinding wheel 13. However, after the rotation of the measuring body 51, both of the light emitter 531 and the light receiver 533 may be positioned outside the region below the grinding wheel 13. When the photoelectric sensor 53 is a diffuse-reflective photoelectric sensor or a retro-reflective photoelectric sensor, the same upper measuring body 511 may be provided with both of the light emitter 531 and the light receiver 533. When the photoelectric sensor 53 is a diffuse-reflective photoelectric sensor, the first upper measuring body component 511a may be provided with both the light emitter 531 and the light receiver 533. When the photoelectric sensor 53 is a diffuse-reflective photoelectric sensor, the second upper measuring body component 511b may be omitted. When the photoelectric sensor 53 is a retro-reflective photoelectric sensor, the first upper measuring body component 511a may be provided with both the light emitter 531 and the light receiver 533. When the photoelectric sensor 53 is a retro-reflective photoelectric sensor, the second upper measuring body component 511b may be provided with a retro-reflective plate.

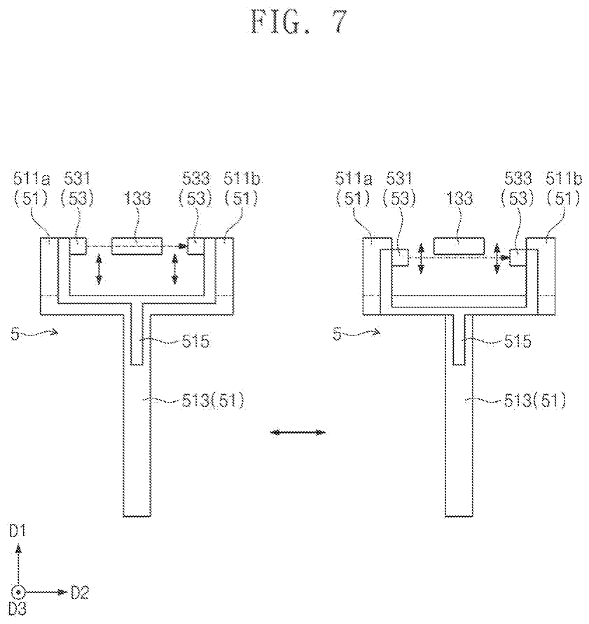

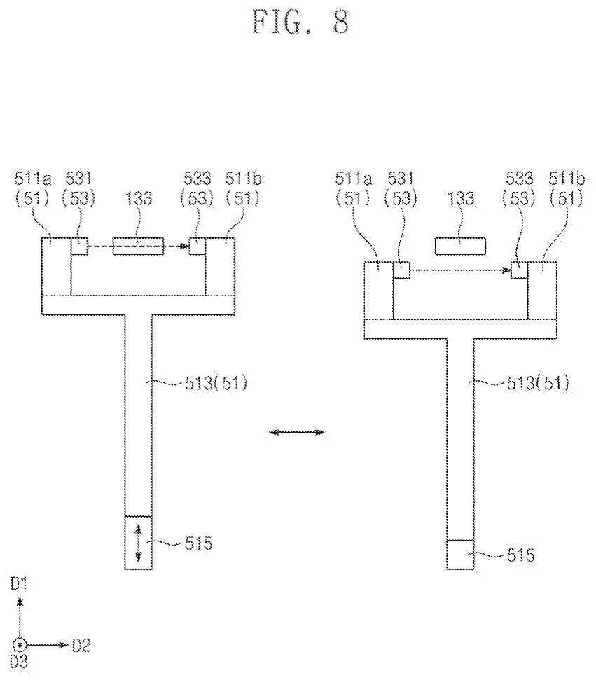

FIG. 7 is a front view illustrating a grinding gauge 5 according to one or more example embodiments. FIG. 8 is a front view illustrating a grinding gauge 5 according to one or more example embodiments.

Referring to FIGS. 7 and 8, the measuring body 51 may further include an actuator 515. The actuator 515 may include, for example, an electric actuator, a hydraulic actuator, or a pneumatic actuator. The pneumatic actuator may move a piston by using air or compressive gas of a cylinder. The hydraulic actuator may use a non-compressive liquid. The hydraulic actuator may generate a force greater than those of other type actuators. The electric actuator may include an alternating-current motor or a direct-current motor. An electric linear actuator may convert a rotation motion of an alternating-current or direct-current motor into a linear reciprocating motion of the alternating-current or direct-current motor. The electric linear actuator may include but not limited to a helical gear or any other suitable components. The electric linear actuator may include one of a linear direct-current motor, a linear synchronous motor, a linear induction motor, and a linear stepping motor. The actuator 515 may include a cylinder. Referring to FIG. 7, the actuator 515 may be directly or indirectly connected to the photoelectric sensor 53. The actuator 515 may drive the photoelectric sensor 53 to vertically move relative to the lower measuring body 513. Referring to FIG. 8, the actuator 515 may be provided on the lower measuring body 513. The actuator 515 may move the upper measuring body 511 and the lower measuring body 513 vertically. The actuator 515 may move the light emitter 531 and the light receiver 533 vertically. The vertically moving photoelectric sensor 53 may analyze the light emitted from the light emitter 531. As the light is analyzed, a wear amount of the abrasive 133 and a variation in height of the abrasive 133 may be measured.

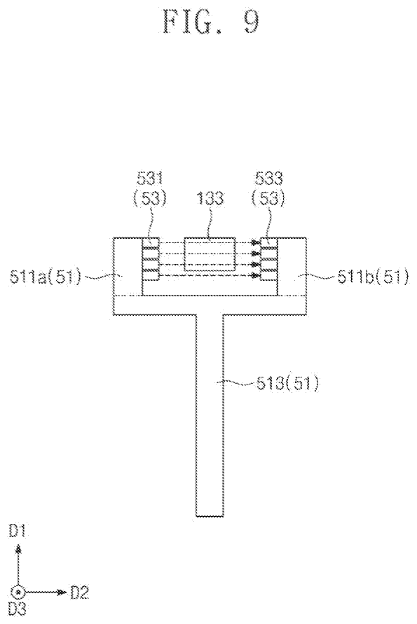

FIG. 9 is a front view illustrating a grinding gauge 5 according to one or more example embodiments. Referring to FIG. 9, the photoelectric sensor 53 may include a plurality of light emitters 531 and a plurality of light receivers 533. For example, the photoelectric sensor 53 may be configured as an area photoelectric sensor (i.e., a photoelectric sensor configured to cover a larger area of the upper measuring body 511 such that the sensor may measure an area of an abrasive). The plurality of light emitters 531 may be arranged vertically. The plurality of light receivers 533 may be arranged vertically. The plurality of light emitters 531 and the plurality of light receivers 533 may measure a height of the abrasives 133, without vertical movement of the photoelectric sensor 53. When the photoelectric sensor 53 is configured as an area photoelectric sensor, a wear amount of the abrasive 133 may be measured without the actuator 515. The disclosure, however, is not limited thereto, and the measuring body 51 may include the actuator 515 even when the photoelectric sensor 53 is an area photoelectric sensor.

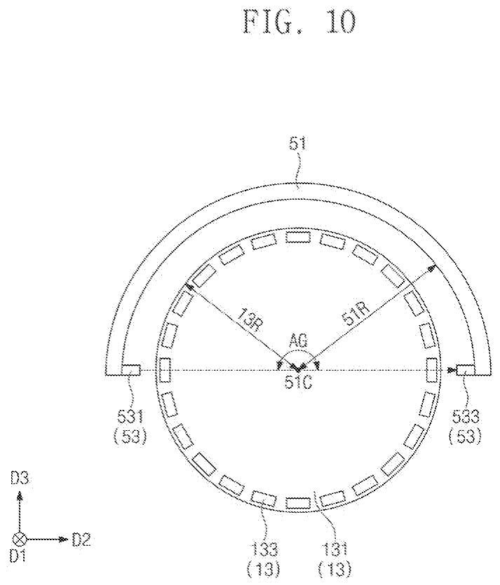

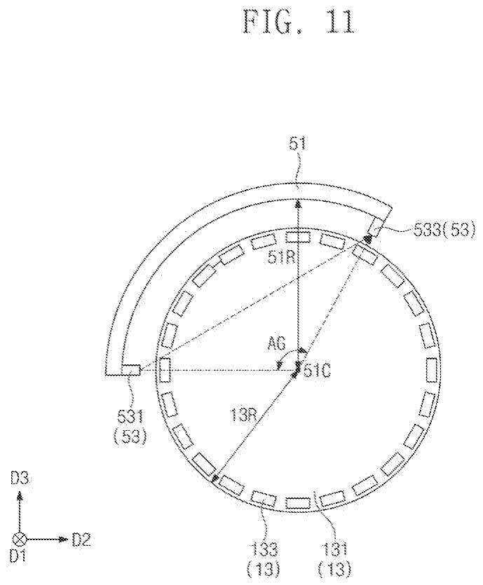

FIG. 10 is a bottom view illustrating a grinding wheel 13 and a grinding gauge 5 according to one or more example embodiments. FIG. 11 is a bottom view illustrating a grinding wheel 13 and a grinding gauge 5 according to one or more example embodiments.

Referring to FIGS. 10 and 11, the measuring body 51 may be shaped as an arc that extends in a circumferential direction. The arc may have a curvature center 51C coincident with a center 51C of the grinding wheel 13. The arc may have a curvature radius 51R greater than a radius 13R of the grinding wheel 13. One side of the measuring body 51 may include the light emitter 531. Another side of the measuring body 51 may include the light receiver 533. An angle AG made between the light emitter 531, the curvature center 51C of the arc, and the light receiver 533 may be about 180°, but the disclosure is not limited thereto. The angle AG made between the light emitter 531, the curvature center 51C of the arc, and the light receiver 533 may range from about 30° to about 330°. A plurality of abrasives 133 may be positioned on a straight path that links the light emitter 531 with the light receiver 533. When the light emitted from the light emitter 531 passes through all of the plurality of abrasives 133, the light receiver 533 may receive the light. Alternatively, when the light emitted from the light emitter 531 passes through all of the plurality of abrasives 133, there may be a reduction in intensity of the light received by the light receiver 533. When the light emitted from the light emitter 531 does not pass through the plurality of abrasives 133, the light receiver 533 may not receive the light.

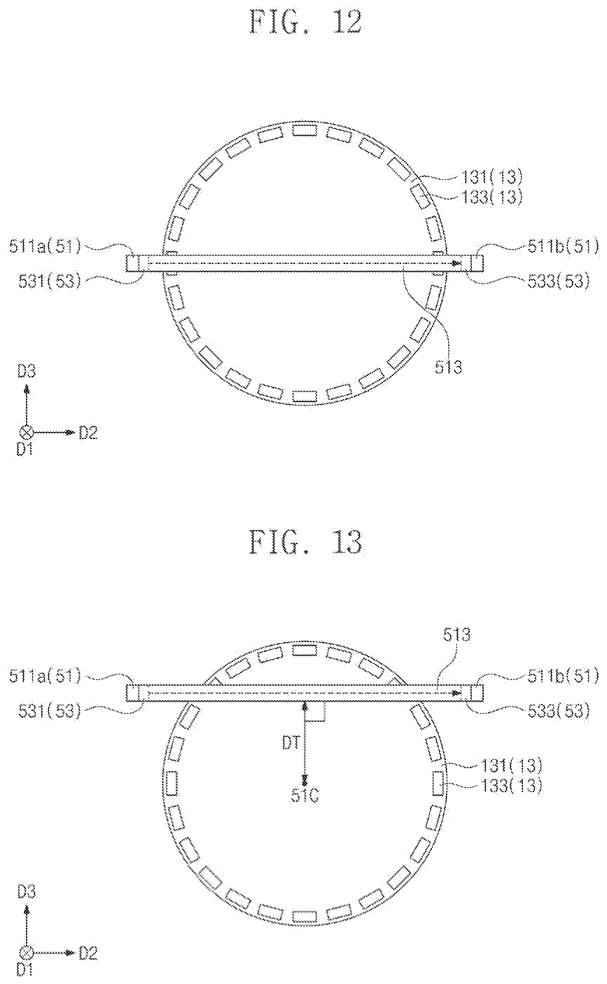

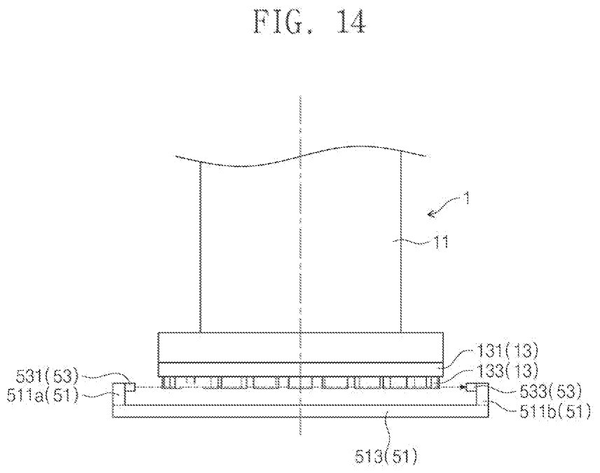

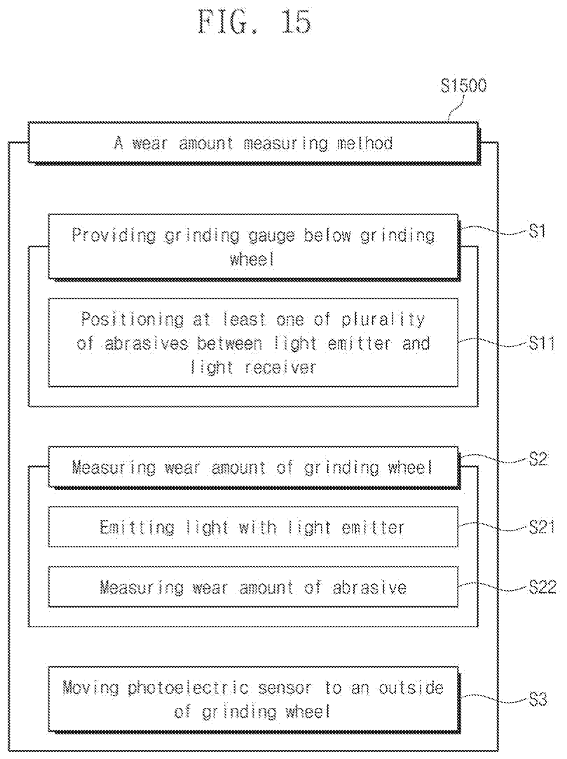

FIG. 12 is a bottom view illustrating a grinding wheel 13 and a grinding gauge 5 according to one or more example embodiments. FIG. 13 is a bottom view illustrating a grinding wheel 13 and a grinding gauge 5 according to one or more example embodiments. FIG. 14 is a front view illustrating a spindle assembly 1 and a grinding gauge 5 according to one or more example embodiments. Referring to FIGS. 12 to 14, the measuring body 51 may have a straight shape. The measuring body 51 may extend across the grinding wheel 13. One side of the measuring body 51 may include the light emitter 531. Another side of the measuring body 51 may include the light receiver 533. The light emitter 531 and the light receiver 533 may be disposed spaced apart from each other, such that the plurality of abrasives 133 are positioned between the light emitter 531 and the light receiver 533. Referring to FIG. 12, the measuring body 51 may pass through the center 51C of the grinding wheel 13. For example, a distance DT of zero may be provided between the measuring body 51 and the center 51C of the grinding wheel 13. The disclosure, however, is not limited thereto, and as illustrated in FIG. 13, the distance DT between the measuring body 51 and the center 51C of the grinding wheel 13 may range from about zero to about the radius 13R of the grinding wheel 13. Referring to FIG. 14, a plurality of abrasives 133 may be positioned between the light emitter 531 and the light receiver 533. When the light emitted from the light emitter 531 passes through all of the plurality of abrasives 133, the light receiver 533 may receive the light. Alternatively, when the light emitted from the light emitter 531 passes through all of the plurality of abrasives 133, there may be a reduction in intensity of the light received by the light receiver 533. When the light emitted from the light emitter 531 does not pass through the plurality of abrasives 133, the light receiver 533 may not receive the light.

FIG. 15 is a flowchart illustrating a wear amount measuring method S1500 according to one or more example embodiments.

Referring to FIG. 15, a wear amount measuring method S1500 may be provided. The wear amount measuring method S1500 may include providing the grinding gauge 5 below the grinding wheel 13 in operation S1, measuring a wear amount of the grinding wheel 13 with the grinding gauge 5 in operation S2, and moving the photoelectric sensor 53 to an outside of the grinding wheel 13 in operation S3. The providing operation S1 may include positioning at least one of the plurality of abrasives 133 between the light emitter 531 and the light receiver 533 in operation S11. The measurement operation S2 may include emitting light with the light emitter 531 in operation S21 and measuring a wear amount of the abrasive 133 in operation S22.

The measurement operation S2 may further include measuring the wear amount of the abrasive 133 in operation S22, which may include rotating the grinding wheel 13. The plurality of abrasives 133 may pass between the light emitter 531 and the light receiver 533 while the grinding wheel 13 rotates. The photoelectric sensor 53 may measure the wear amount of the plurality of abrasives 133, while measuring a height of the plurality of abrasives 133. The measurement operation S2 may be performed by changing a relative distance between the grinding gauge 5 and the grinding wheel 13. For example, the measurement operation S2 may further include, after emitting light with the light emitter 531 (operation S21), vertically moving the light emitter 531 and the light receiver 533 by the actuator 515. For another example, the measurement operation S2 may further include, after emitting light with the light emitter 531 (operation S21), vertically moving the grinding wheel 13 by the driver 11.

According to a back grinding apparatus and a wear amount measuring method using the same in accordance with some embodiments of the disclosure, a wear amount of abrasive may be measured irrespective of substrate dispersion. A light emitter and a light receiver may be used to measure a change in height of abrasive, thereby determining a wear amount of abrasive.

According to a back grinding apparatus and a wear amount measuring method using the same in accordance with some embodiments of the disclosure, a grinding gauge may be prevented from interrupting a substrate insertion procedure. For example, the grinding gauge may be disposed outside a grinding wheel, and this may not interfere with substrate movement. In such cases, a rotary motor may cause the grinding gauge to deviate from a vertical movement range of the grinding wheel, and thus the substrate movement may be free of interruption.

According to a back grinding apparatus and a wear amount measuring method using the same in accordance with some embodiments of the disclosure, a wear amount of a plurality of abrasives may be directly measured between a light emitter and a light receiver.

According to a back grinding apparatus and a wear amount measuring method using the same of the disclosure, a wear amount of grinding wheel abrasive may be measured.

According to a back grinding apparatus and a wear amount measuring method using the same of the disclosure, a wear amount of grinding wheel abrasive may be measured irrespective of substrate dispersion.

According to a back grinding apparatus and a wear amount measuring method using the same of the disclosure, a photoelectric sensor may be used to measure a wear amount of abrasive.

According to a back grinding apparatus and a wear amount measuring method using the same of the disclosure, a grinding gauge may be caused to move to an outside of a grinding wheel.

Effects of the disclosure is not limited to the mentioned above, other effects which have not been mentioned above will be clearly understood to those skilled in the art from the following description.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A back grinding apparatus comprising:
a grinding wheel that is rotatable and movable in a vertical direction, the grinding wheel comprising at least one abrasive; and
a grinding gauge below the grinding wheel and configured to measure a wear amount of the at least one abrasive,
wherein the grinding gauge comprises:
a measuring body; and
a photoelectric sensor supported by the measuring body and configured to determine the wear amount of the at least one abrasive, and
wherein the photoelectric sensor comprises:
at least one light emitter; and
at least one light receiver spaced apart from the at least one light emitter in a horizontal direction and configured to receive light emitted from the at least one light emitter.

2. The back grinding apparatus of claim 1, wherein the grinding gauge further comprises a rotary motor connected to the measuring body, the rotary motor being configured to rotate the measuring body and cause the grinding gauge to move to an outside of the grinding wheel.

3. The back grinding apparatus of claim 1, wherein the measuring body comprises:
an upper measuring body comprising the photoelectric sensor;
a lower measuring body supporting the upper measuring body; and
an actuator configured to move the photoelectric sensor relative to the lower measuring body in the vertical direction,
wherein the upper measuring body comprises a first upper measuring body component and a second upper measuring body component,
wherein the at least one light emitter is provided on the first upper measuring body component, and
wherein the at least one light receiver is provided on the second upper measuring body component.

4. The back grinding apparatus of claim 1, wherein the measuring body comprises:
an upper measuring body comprising the photoelectric sensor;
a lower measuring body supporting the upper measuring body; and
an actuator configured to move the upper measuring body and the lower measuring body in the vertical direction.

5. The back grinding apparatus of claim 1, wherein the at least one light emitter comprises a plurality of light emitters arranged vertically, and
wherein the at least one light receiver comprises a plurality of light receivers arranged vertically.

6. The back grinding apparatus of claim 1, wherein the grinding wheel further comprises a wheel body supporting the grinding wheel,
wherein the at least one abrasive comprises a plurality of abrasives, and
wherein the plurality of abrasives are spaced apart in a circumferential direction on a first surface of the wheel body.

7. The back grinding apparatus of claim 6, wherein the measuring body extends across the grinding wheel, and
wherein the at least one light emitter and the at least one light receiver are spaced apart such that the plurality of abrasives are positioned between the at least one light emitter and the at least one light receiver.

8. A back grinding apparatus comprising:
a spindle assembly that is rotatable and movable in a vertical direction; and
a grinding gauge below the spindle assembly,
wherein the spindle assembly comprises:
a driver configured to move the spindle assembly in the vertical direction; and
a grinding wheel provided on a lower portion of the driver,
wherein the grinding wheel comprises a plurality of abrasives on a first surface of the grinding wheel and spaced apart in a circumferential direction of the grinding wheel,
wherein the grinding gauge comprises:
a measuring body; and
a photoelectric sensor provided on the measuring body and configured to determine a wear amount of at least one of the plurality of abrasives,
wherein the photoelectric sensor comprises:
at least one light emitter; and
at least one light receiver spaced apart from the at least one light emitter in a horizontal direction, and
wherein the plurality of abrasives are between the at least one light emitter and the at least one light receiver.

9. The back grinding apparatus of claim 8, further comprising a rotatable chuck table configured to support a substrate.

10. The back grinding apparatus of claim 8, wherein the grinding gauge further comprises a rotary motor configured to rotate the measuring body and cause the grinding gauge to move to an outside the spindle assembly.

11. The back grinding apparatus of claim 8, wherein the measuring body comprises:
an upper measuring body comprising the photoelectric sensor; and
a lower measuring body supporting the upper measuring body.

12. The back grinding apparatus of claim 11, wherein the grinding gauge further comprises an actuator connected to the photoelectric sensor, the actuator configured to move the photoelectric sensor relative to the lower measuring body in the vertical direction.

13. The back grinding apparatus of claim 11, wherein the grinding gauge further comprises an actuator provided on the lower measuring body, the actuator configured to move the upper measuring body and the lower measuring body in the vertical direction.

14. The back grinding apparatus of claim 8, wherein the photoelectric sensor comprises a plurality of light emitters and a plurality of light receivers,
wherein the plurality of light emitters comprises the at least one light emitter, and
wherein the plurality of light receivers comprises the at least one light receiver.

15. The back grinding apparatus of claim 8, wherein the measuring body has an arc shape extending in a circumferential direction,
wherein a center of the arc shape is coincident with a center of the grinding wheel, and
wherein a radius of the arc shape is greater than a radius of the grinding wheel.

16. The back grinding apparatus of claim 8, wherein the measuring body extends across the grinding wheel, and
wherein the at least one light emitter and the at least one light receiver are spaced apart such that the plurality of abrasives are positioned between the at least one light emitter and the at least one light receiver.

17. A wear amount measuring method comprising:
providing a grinding gauge below a grinding wheel; and
measuring a wear amount of the grinding wheel,
wherein the grinding wheel comprises:
a wheel body; and
a plurality of abrasives on a bottom surface of the wheel body and spaced apart along an edge of the wheel body,
wherein the grinding gauge comprises:
a measuring body;
at least one light emitter; and
at least one light receiver spaced apart from the at least one light emitter in a horizontal direction,
wherein providing the grinding gauge below the grinding wheel comprises positioning at least one of the plurality of abrasives between the at least one light emitter and the at least one light receiver, and
wherein measuring the wear amount of the grinding wheel comprises:
emitting light by the at least one light emitter toward at least one of the plurality of abrasives; and
measuring a wear amount of the at least one of the plurality of abrasives based on the light emitted by the at least one light emitter.

18. The wear amount measuring method of claim 17, wherein the grinding gauge further comprises an actuator configured to move the at least one light emitter and the at least one light receiver in a vertical direction,
wherein measuring the wear amount of the grinding wheel comprises includes at least one of:
rotating the grinding wheel; and
moving, by the actuator, the at least one light emitter and the at least one light receiver in the vertical direction after light is emitted by the at least one light emitter.

19. The wear amount measuring method of claim 17, wherein the at least one light emitter comprises a plurality of light emitters arranged vertically; and
wherein the at least one light receiver comprises a plurality of light receivers arranged vertically.

20. The wear amount measuring method of claim 17, wherein the grinding wheel comprises a driver configured to move the grinding wheel in a vertical direction, and
wherein measuring the wear amount of the grinding wheel further comprises moving, by the driver, the grinding wheel in the vertical direction after light is emitted from the at least one light emitter.
